(19) United States
(12) Patent Application Publication
(10) Pub. No.: US 2007/0145424 A1
(43) Pub. Date: Jun. 28, 2007

(54) IMAGE SENSOR, CONTROLLING METHOD OF THE SAME, X-RAY DETECTOR AND X-RAY CT APPARATUS

(76) Inventors: Koji Bessho, Tokyo (JP); Masahiro Moritake, Tokyo (JP)

Correspondence Address: Patrick W. Rasche;Armstrong Teasdale LLP, Suite 2600, One Metropolitan Square, St. Louis, MO, 63102, US

(21) Appl. No.: 11/614,342

(22) Filed: Dec. 21, 2006

(30) Foreign Application Priority Data
Dec. 28, 2005 (JP) 2005-377496

(51) Int. Cl. H01L 27/148

(52) U.S. Cl. 257/233

(57) ABSTRACT

The present invention provides always stably sampling a high quality image irrespective of the displacement of a subject, with a simpler arrangement. The image sensor in accordance with the present invention includes a plurality of photodiodes arranged in a two-dimensional array and a plurality of read out gate circuits for reading out the photoelectric conversion charge accumulated in the photoreceptor of each of the photodiodes, in which first and second gate electrodes are provided in the opposing side of an insulator layer for forming respectively first and second potential wells in the vicinity of each of the photoreceptor, charge stored in each photoreceptor for a predetermined period of time is sequentially transferred to the first and second potential wells each at once, a potential barrier is formed for blocking the movement of charge between the photoreceptor and the second potential well by disappearing the first potential well, and charge accumulated in the second potential well is read out in a time division basis.

### BACKGROUND OF THE INVENTION

The present invention relates to an image sensor, controlling method thereof, X-ray detector, and X-ray CT apparatus, and more specifically to an image sensor which includes a plurality of photodiodes two-dimensionally arranged, and a plurality of read gate circuits for reading out the photoelectric conversion charge stored in the photoreceptor units of the photodiodes, the controlling method thereof, X-ray detector, and X-ray CT apparatus.

In an X-ray CT apparatus, in general, X-ray transmitted through a subject is converted to light in the scintillator layer, and the light signal thus obtained is further converted into electric signal in the photodiode array (image sensors). An example will be described herein below. FIG. 11 and FIG. 12 are schematic diagrams of the prior art (1) and (2), FIG. 11 illustrates a partial plan view of a multi slice X-ray detector of the prior art. In the figure the arrow X indicates the direction of channels of the X-ray detector, the arrow Z indicates the direction of slice (body axis of the subject).

On the backside of the frontmost scintillator layer (CsI, etc.) there is a plurality of photodiodes PD11 to PD33 being arranged in a two-dimension, each of which has a gate circuit (MOSFET switching circuit) for reading the charge stored in the photoreceptor. The photodiodes of the first row PD11, PD12, PD13 arranged in the slice (row) direction have respective output terminal (drain D) connected to a common read line DR1, an end of the line is connected to an amplifier circuit AR1 of the type current integration. The second and third rows are arranged in the same way, these are connected to amplifier circuits AR2 and AR3, respectively.

The first column of photodiodes PD11, PD21, PD31 arranged in the channel (column) direction have their gate terminals (G) connected to a common read control line GC1, an end of the line is connected to a driving switch S1. The second and third columns are arranged in the same way, these are connected to switches S2 and S3, respectively.

In such an arrangement, the switch S1 is momentarily closed to apply a pulse voltage to the gate G of each FET switch connected to PD11, PD21, PD31 in the first column, the charge stored in the photoreceptors will be read out to their respective read lines DR1 to DR3 at once (at the same time). Then the switch S2 is momentarily closed to read out the charge stored in the photoreceptors of PD12, PD22, PD32 of the second column onto their respective read lines DR1 to DR3 at once (at the same time). The same is applied to the rest. Thus the stored charge of PDs arranged in the channel direction will be read out at once while the stored charge of PDs arranged in the slice direction will be read out sequentially in a time division basis.

FIG. 12 shows a timing chart of the multi slice X-ray detector of the prior art. In the figure, the photoelectric conversion charge stored in a predetermined period of time T of the PD11 of the first column will be read out at the timing of gate signal GC1. The charge stored in the period of time T of the PD12 in the second column will be read out at the timing of gate signal GC2, which is shifted by the time Δt. The same is applied to the rest. As can be seen the X-ray detector of the prior art has the phase of the charge storage time T of PDs arranged in the slice direction shifted by the time Δt.

Some examples of multi slice X-ray detectors having a plurality of photodiodes arranged in a two-dimensional array are disclosed in JP-A-2005-189022 and JP-A-2004-65285.

In the X-ray CT apparatus of the recent years, the scanning gantry revolves faster, causing the X-ray detector to be displaced by an enough long distance around the body axis during one storage time T. As a result the first column will have a projection image shifted by the view angle of the storage time T from the m'th column. This affects the image reconstruction processing as well as the reconstructed image.

In particular, when sampling the projection data by switching the focal point of the X-ray generation for each view, it is possible for one column that the switching timing from a preceding charge storage time T to a succeeding charge storage time T may be matched with the switching timing of the X-ray focal point so as to acquire some data of sufficiently high spatial resolution. However, for another column in that case, because the switching timing of the charge storage time T will not be exactly matched with the switching timing of the X-ray focal point so that the X-ray focal point will move during the period of one charge storage time T, resulting in a problem that the blur of the data position occurs. When attempting to switch the X-ray focal point to sample some fine data, only insufficient spatial resolution of thus obtained projection data can be obtained, thus an image having a sufficiently fine spatial resolution cannot be obtained.

### SUMMARY OF THE INVENTION

The present invention has been made in view of the above circumstances and has a subject to provide an image sensor and the controlling method of the same, X-ray detector, as well as an X-ray CT apparatus, which allows sampling stably high quality images all the time with a simple arrangement even though the subject moves or the X-ray focal point (light source position) is switched.

The problem described above may be solved by the arrangement shown in FIG. 3. More specifically, the image sensor in accordance with the present invention (1) is an image sensor incorporating a plurality of photodiodes PD arranged in a two-dimensional array, and a plurality of read-out gate circuits for reading out the photoelectric conversion charge stored in the photoreceptors of the photodiodes, in which there are provided first and second gate electrodes A, S for forming first and second potential wells in the vicinity of the photoreceptors via an insulator layer, the charge stored in the photoreceptors for the predetermined period of time T is transferred at once to the first and second potential wells sequentially, then a potential barrier is formed by disappearing the first potential well for blocking the displacement of charge between the photoreceptors and second potential well, then the charge stored in the second potential well is read out to an outside in a time division basis.

In the present invention (1), potential wells (potential area of the well type) A, S are formed in the next stage of the photoreceptor. The photoelectric conversion charge stored in T at once (at the same time) in the photoreceptor will be sequentially transferred to the first and second potential wells A, S at once, thereafter to shield between the photoreceptor and the second potential well S. The charge stored in the second potential well S will be read out in a time division basis. With this simpler arrangement, a higher quality image can be sampled all the time irrespective of the displacement of the subject.

In the present invention (2), in accordance with the present invention (1) described above, as shown in FIG. 7, there are provided third and fourth gate electrodes C, B via an insulator layer for forming third and fourth potential wells between the photoreceptors and first potential well, the charge to be stored in the photoreceptors for the predetermined period of time T will be sequentially transferred to the third and fourth potential wells at once for a plurality of times, then the third potential well will be disappeared each time so as to form the potential barrier between the photoreceptor and the fourth potential well in order to block the movement of charge, and the charge integrated in the fourth potential well will be sequentially transferred to the first and second potential wells at once.

In the present invention (2), there are provided third and fourth potential wells C, B between the photoreceptors and the first potential well A. The charge to be charged in the photoreceptors for the predetermined period of time T will be transferred to the third and fourth potential wells at once for a plurality of times, and shielding between the photoreceptors and the fourth potential well each time so as to store (integrate) the photoelectric conversion charge developed in the photoreceptors into the fourth potential well at a higher efficiency (i.e., at a lower loss). This allows a higher linearity in the detection characteristics.

In the present invention (3), in accordance with the above invention (1) or (2), there is provided a common amplifier circuit for each of row or column of the sensor elements arranged in a two-dimensional array, so that the charge stored in the second potential well of each sensor element is to be read out in a time division basis in either the row direction or the column direction.

The controlling method of the image sensor of the present invention (4) is a controlling method of an image sensor having first and second gate electrodes provided for forming first and second potential wells each placed in the proximity to the photoreceptor of each photodiode, and a plurality of read-out gate circuits for reading out the charge stored in the second potential well, the method comprises, as shown in FIG. 4, a step of storing in the photoreceptor the charge developed in the photoreceptor for the predetermined period of time T, a step of transferring sequentially the charge stored in the photoreceptor to first and second potential wells at once, then disappearing the first potential well to form a potential barrier for blocking the transfer of charge between the photoreceptor and the second potential well, and a step of reading out the charge stored in the second potential well in a time division basis.

The controlling method of the image sensor of the present invention (5) is a controlling method of an image sensor having a plurality of photodiodes arranged in a two-dimensional array, third, fourth and first, second gate electrodes provided next to the photoreceptor of each photodiode for forming third, fourth, and first, second potential wells, and a plurality of read-out gate circuits for reading out the charge eventually stored in the second potential well, the method comprises, for example as shown in FIG. 8, a step for sequentially transferring the charge to be stored in each photoreceptor for a predetermined period of time T to third and fourth potential wells each at once for a plurality of times (φ C) then forming a potential barrier for blocking the movement of charge between the photoreceptor and the fourth potential well by disappearing the third potential well, a step for sequentially transferring the charge integrated in the fourth potential well into the first and second potential wells and then forming a potential barrier for blocking the movement of charge between the fourth potential well and the second potential well by disappearing the first potential well, and a step for reading out the charge stored in the second potential well in a time division basis.

An X-ray detector of the present invention (6) includes a scintillator layer for converting X-ray into light, the scintillator layer being fixedly laminated on the light receiving plane of the image sensor in accordance with the invention (1) or (2).

An X-ray detector of the present invention (7) includes an X-ray tube and the X-ray detector in accordance with the present invention (6) placed in the opposing sides of a subject, used as an X-ray detector of an X-ray CT apparatus for reconstructing a CT tomographic image of the subject based on the projection data obtained by scanning the subject, the detector comprises a common amplifier circuit in the slice direction of each channel of the sensor elements arranged in a two-dimensional array extending in the slice direction which is in parallel to the body axis of the subject, and in the channel direction which is perpendicular thereto, for reading out the charge stored in the second potential well of each sensor element arranged in the channel direction at once, and the charge stored in the second potential well of each sensor element arranged in the slice direction in a time division basis.

An X-ray CT apparatus of the present invention (8) includes the X-ray detector in accordance with the above present invention (7), allowing sampling the projection data of the same view angle in the slice direction even when the scanning gantry is revolving at higher speed, as well as allowing appropriately sampling the projected image when sampling the projection data by switching the focal point of the X-ray generation for each view because every sensor elements can store the charge at the identical timing.

As have been described above, in accordance with the present invention, the picture of the subject can be sampled at the same time with a simpler arrangement, resulting in a considerable contribution to the improvement of the picture and the CT reconstruction image.

### BRIEF DESCRIPTION OF THE DRAWINGS

FIG. 1 is a schematic diagram of an X-ray CT apparatus in accordance with the preferred embodiment of the present invention;

FIG. 2 is a schematic diagram of a scanning gantry in accordance with the preferred embodiment of the present invention;

FIG. 3 is a schematic plan view of a photodiode array in accordance with first preferred embodiment of the present invention;

FIG. 4 is a schematic timing chart of the photodiode array in accordance with the first preferred embodiment of the present invention;

FIG. 5 is a schematic diagram (1) illustrating the operation of the photodiode array in accordance with the first preferred embodiment of the present invention;

FIG. 6 is a schematic diagram (2) illustrating the operation of the photodiode array in accordance with the first preferred embodiment of the present invention;

FIG. 7 is a schematic plan view of a photodiode array in accordance with second preferred embodiment of the present invention;

FIG. 8 is a schematic timing chart of the photodiode array in accordance with the second preferred embodiment of the present invention;

FIG. 9 is a schematic diagram (1) illustrating the operation of the photodiode array in accordance with the second preferred embodiment of the present invention;

FIG. 10 is a schematic diagram (2) illustrating the operation of the photodiode array in accordance with the second preferred embodiment of the present invention;

FIG. 11 is a schematic diagram (1) illustrating a prior art; and

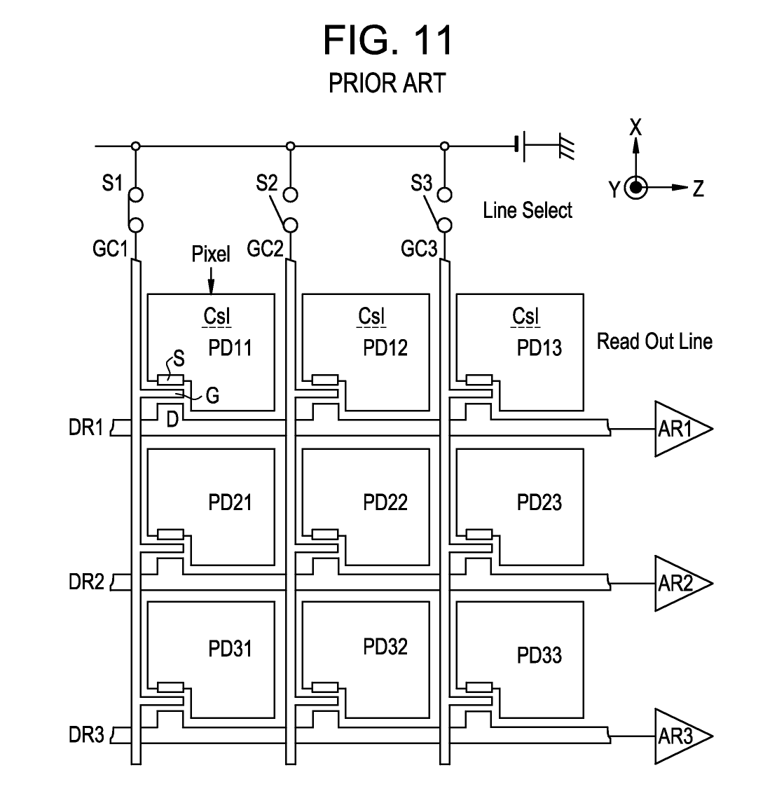

FIG. 12 is a schematic diagram (2) illustrating a prior art.

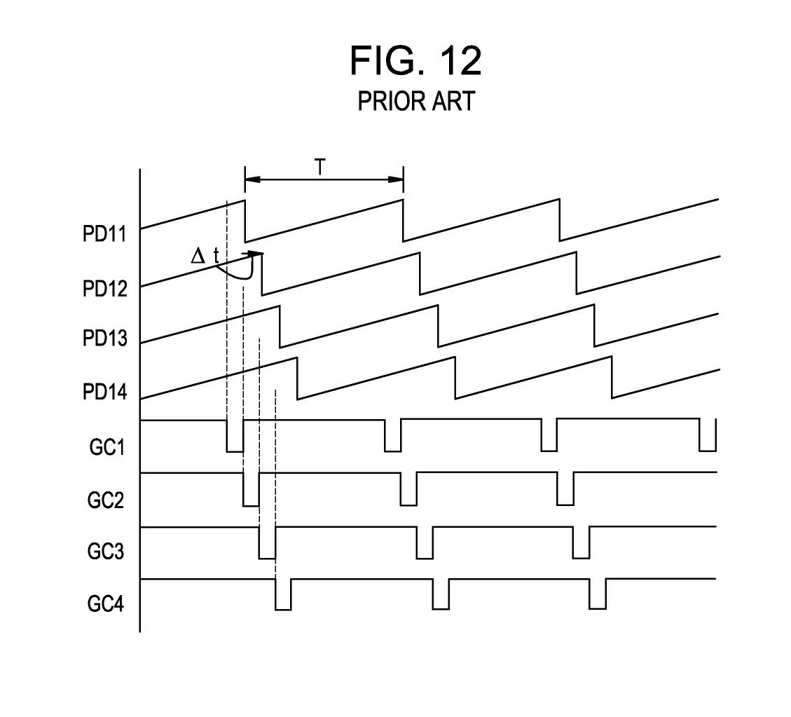

### DETAILED DESCRIPTION OF THE INVENTION

Some preferred embodiments of the present invention will be described in greater details with reference to the accompanying drawings. In the drawings the identical or similar member is designated to the same reference numerals.

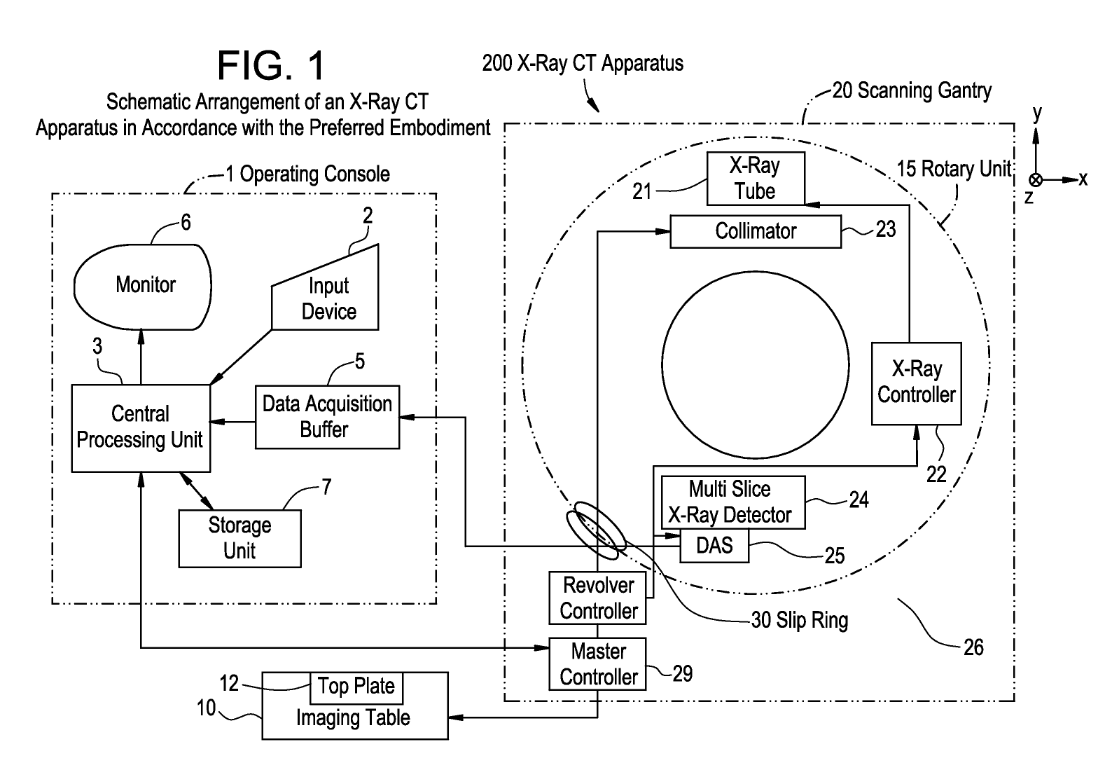

Now referring to FIG. 1, there is a schematic block diagram of an X-ray CT apparatus 200 in accordance with the preferred embodiment, illustrating an exemplary application of the image sensor (photodiode array) in accordance with the present invention into an X-ray detector. The X-ray CT apparatus includes an imaging table 10 for carrying thereon a subject and for translating in the direction of body axis (z), a scanning gantry 20 for performing the data acquisition by the axial/helical scan of the subject by means of X-ray fan beam, and an operating console 1 for remotely controlling the imaging table 10 and the scanning gantry 20 as well as for the operator to perform various setting work.

The operating console 1 includes an input device 2 for receiving the input from the operator, a central processing unit (CPU) 3 for performing the image reconstruction processing, etc., a data acquisition buffer 5 for acquiring the projection data obtained by the scanning gantry 20, a monitor 6 for displaying a CT image reconstructed from the projection data, and a storage unit 7 for storing a program, data, and X-ray CT images for achieving the functionality of the apparatus. The imaging table 10 includes a top plate (cradle) 12 and a driving unit for mounting the subject and carrying in and out of the bore (central void) of the scanning gantry 20.

The scanning gantry 20 includes an X-ray tube 21, an X-ray controller 22 for controlling the tube voltage and tube current of the X-ray tube 21, a collimator 23 for controlling the thickness (slice thickness) in the z-axis direction of the X-ray fan beam, a multi slice X-ray detector 24 for obtaining simultaneously the projection data of a plurality of column, a DAS (data acquisition system) 25 for acquiring projection data of each column, a revolver unit 15 for rotatably supporting the X-ray tube 21, multi slice X-ray detector 24 and the like around the body axis of the subject, a revolver controller 26 for controlling the revolver, and a master controller 29 for communicating the control signals to and from the operating console 1 and the imaging table 10.

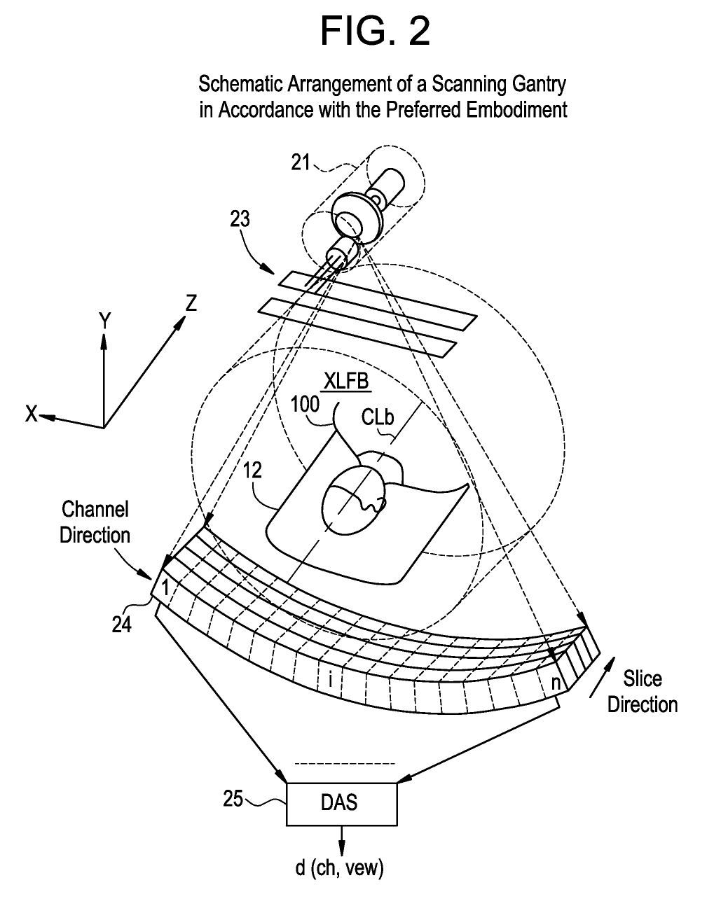

Now referring to FIG. 2, there is shown a schematic diagram of the scanning gantry 20 in accordance with the preferred embodiment. The X-ray tube 21 and the multi slice X-ray detector 24 are placed in the opposing sides of a subject 100, both being supported rotatably around the body axis of the subject CLb. The X-ray focal point of the X-ray tube 21 is arranged such that the collision point (i.e., X-ray generation focal point) can be changed in a short period of time for each view by the control of the electron beam collision point by means of the X-ray controller 22. The multi slice X-ray detector 24 has a plurality of (for example, about 1000) X-ray detector elements in the channel direction (x-axis), and the X-ray detector elements are provided in a plural manner (for example, 16, 32, 34 columns) in the slice direction (z-axis).

The acquisition of projection data with the arrangement described above will be as follows. Firstly, the subject is placed within the bore of the scanning gantry 20, and the position in the z-axis direction is fixedly held. The X-ray tube 21 emits X-ray fan beam to the subject, and the multi slice X-ray detector 24 detects the transmitted X-ray. The detection of the transmitted X-ray is such that the X-ray tube 21 and the multi slice X-ray detector 24 revolves around the subject (i.e., by changing the projection (view) angle), while at the same time the X-ray focal point is switched for each view, in this way data will be acquired for 360 degrees in a plurality N (for example, n=1,000 or so) of the view directions.

The transmitted X-ray thus detected will be converted to digital values in the DAS 25 then transferred to the operating console 1 through the data acquisition buffer 5 as the projection data d (ch, view) (where ch=channel, view=view). This cycle is referred to as one “scan”. Next the scan position will be sequentially displaced by a predetermined amount of distance in the direction of z-axis for the next scan. This type of scan is referred to as the conventional (or axial) scan. In this conventional scan, a few continuous turns of scans may be performed at once, this is referred to as a cinescan. A helical scan is another type in which the imaging table 10 is moved at a predetermined speed in synchronization with the change of the projection angle to move the scan position while acquiring the projection data. The present invention is equally applicable to the conventional scan, cinescan, and helical scan as well.

The operating console 1 stores the projection data transferred from the scanning gantry 20 into the storage unit 7 of the central processing unit 3, and performs a convolution calculation with a predetermined reconstruction function to reconstruct a tomographic image of the subject by the back projection process. The operating console 1, during the scan is capable of reconstructing a tomographic image at the real time basis from the projection data sequentially transferred from the scanning gantry 20, and displaying the latest tomographic image on the monitor 6. In addition, it is capable of reconstruction of an image by retrieving the projection data already stored in the storage unit 7.

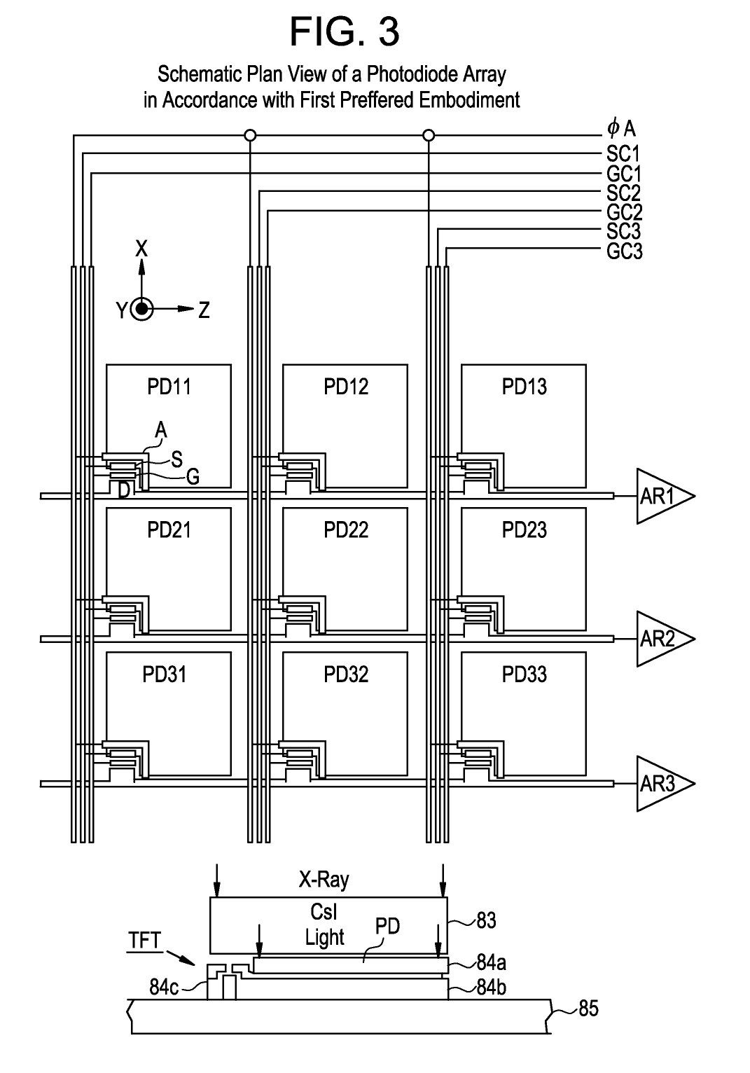

The photodiode array (image sensor) which forms the multi slice X-ray detector described above will be described more specifically. Now referring to FIG. 3, there is shown a partial plan view of a photodiode array in accordance with the first preferred embodiment of the present invention, in which first and second gate electrodes A, S (also called as source electrode S in the sense that the second gate electrode S is the storage charge source to the output circuit) for forming first and second potential wells (potential area of the well type) adjacent to the photoreceptor.

In the figure a plurality of photodiodes PD11 to PD33 are placed arranged in a two-dimension array on the backside of the front-most scintillator layer, on each of which a gate circuit is provided for selectively reading out the charge stored in the photoreceptor. The diodes PD11, PD12, PD13 of the first row arranged in the slice (row) direction have a common read out line connected to their respective output terminal (drain D), at the end of which line an amplifier circuit AR1 of the type charge integration is connected. The second and third rows are of the similar configuration, except that they are connected to amplifier circuits AR2 and AR3, respectively.

The diodes PD11, PD21, PD31 of the first column arranged in the channel (column) direction have their respective gate terminal G connected to a read out control line GC1. The diodes PD12, PD22, PD32 of the second column, the diodes PD13, PD23, PD33 of the third column are of the similar configuration, except that they are connected to the read out control line GC2, GC3, respectively.

In the first preferred embodiment of the present invention, first and second gate electrodes A, S for forming first and second potential wells respectively are provided via the insulator layer so as to be adjacent to the photoreceptor of each PD, in which the photoelectric conversion charge stored in each photoreceptor for a predetermined period of time is sequentially transferred to the first and second potential wells A, S at once. Thereafter a potential barrier is formed by disappearing the first potential well A, for blocking the movement of charge between the photoreceptor and the second potential well S, and the charge stored in the second potential well S will be read out in a time division basis.

In FIG. 3(a) there is shown a cross-sectional side view for one pixel width of the X-ray detector. In the figure the reference numeral 83 designates to a scintillator layer which uses for example cesium iodide (CsI) for the phosphor body, the diffusion of X-ray photon within the scintillator is low because of the columnar crystal structure of the CsI. The reference numeral 84 designates to a TFT (thin film transistor) amorphous silicone layer, including a photodiode layer 84a for converting the light converted by the scintillator layer 83 into electric charge, a read-out gate circuit layer 84b and 84c for reading out thus converted electric charge. The reference numeral 85 designates to a substrate layer comprised of a glass plate for supporting other film layers.

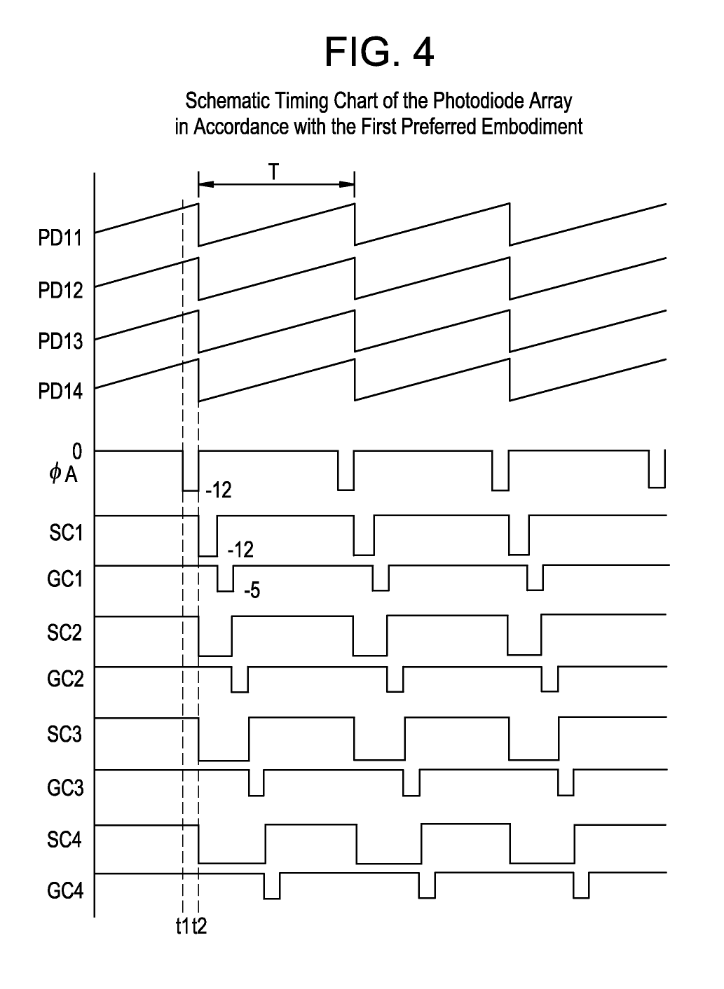

FIG. 4 is a timing chart of the photodiode array in accordance with the first preferred embodiment of the present invention. The photoelectric conversion charge stored in all diodes PD11 to PD44 for a predetermined period of time T will be transferred at once to the first potential wells A each corresponding to one of PD11 to PD44 by a first gate signal φ A (for example, −12V) common to all PDs, and then transferred at once to the corresponding second potential wells (source) S by a second gate signal SC1 to SC4, commonly issued to each column. In this phase the first gate signal φ A is raised again to high level (for example, 0V), so that the first potential wells A will be disappear to form the potential barrier between the photoreceptor and the second potential wells S for blocking the movement of charge. As the charge transferred to each of second potential wells S will be then held in the well, the charge stored in the second potential wells S will be read out column by column on the time division basis.

When considering the first column of PD11, PD21, and PD31, the charge transferred by the gate signal φ A that has been commonly issued to all PDs, will be held in the second potential wells (source) S by the gate signal SC1 for the first column, and then read out at once by the read-out gate signal GC1 for the first column. When considering the second column of PD12, PD22, and PD32, the charge transferred by the gate signal φ A that has been commonly issued to all PDs, will be held in the second potential wells (source) S by the gate signal SC2 for the second column, then read out at once by the read-out gate signal GC2 for the second column, which is issued delayed by the time Δt from the signal GC1. The same is applied to the third column PD and further.

In accordance with the first preferred embodiment of the present invention, all PDs are capable of detecting light at the same phase in the same cycle T. The charge stored in the second potential wells (source) S of each column is read out by the gate signals GC1 to GC4 on the time division basis, ΔT at a time, so that the circuit design of read-out configuration (such as amplifiers) may be significantly simplified.

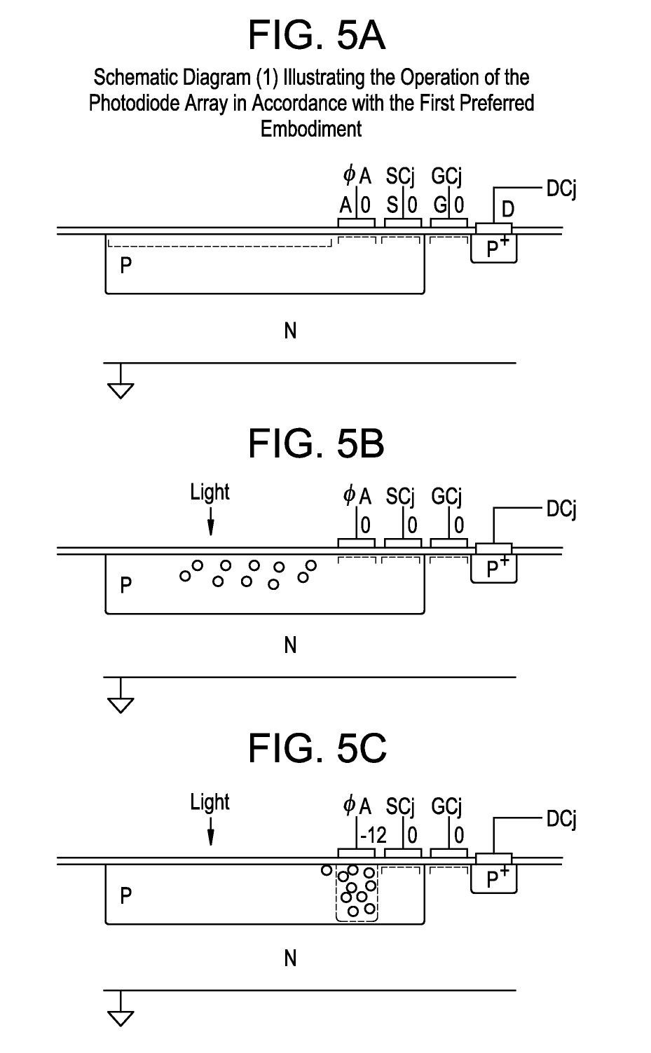

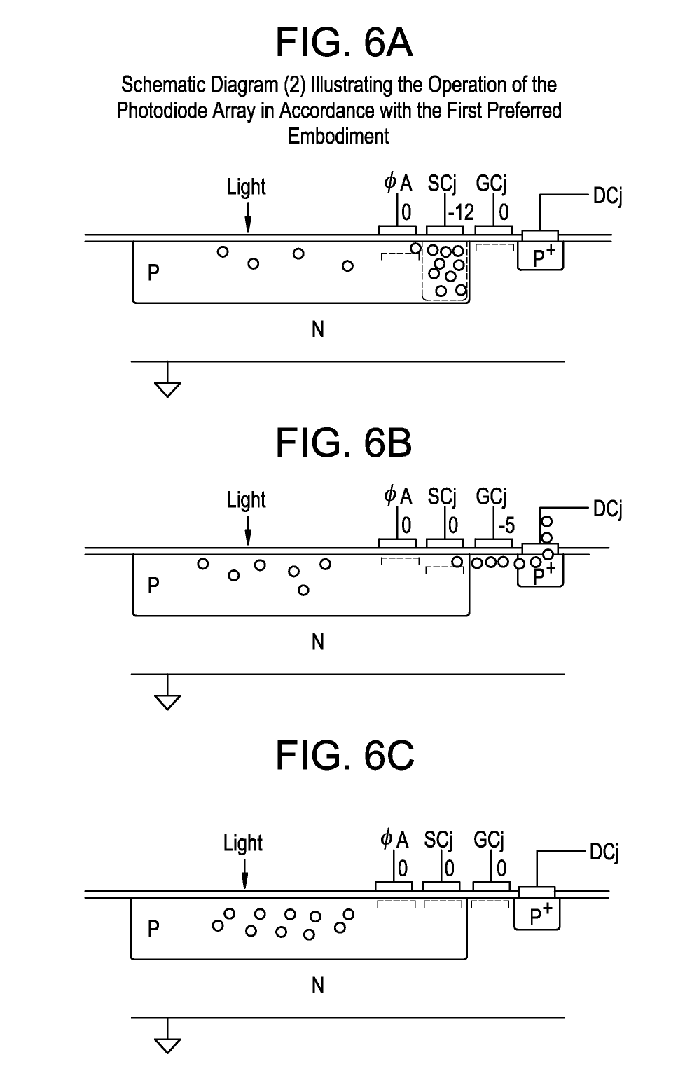

Now referring to FIG. 5 and FIG. 6, there are shown schematic diagrams (1) and (2) illustrating the operation of photodiode array in accordance with the first preferred embodiment of the present invention. In FIG. 5(A), a p-type layer is formed (diffused) on an n-type silicon substrate for example, to form a photodiode of pn junction type. The surface of photoreceptor area is covered by a transparent insulator layer (such as SiO2), provided on the insulator layer adjacent to the photoreceptor area are the first and second gate electrode A, S for forming the first and second potential wells and the gate electrode G for reading out the stored charge. When the substrate N is grounded, p-type layer is self biased to a low potential with respect to the n-type layer. By applying 0V to the gate electrodes A, S, and G, the movement of charge may be blocked. The potential is schematically illustrated by a dotted line. On the drain side for reading out the stored charge, the drain electrode D is ohm connected to the p-type diffusion layer P+, and further connected to an amplifier AR not shown in the figure. This can be considered as a p-channel MOSFET switching circuit made by the p-type layer of the electrode S, n-type layer of the electrode G, and the P+layer of the electrode D.

In FIG. 5(B), when light is incident to the pn junction, electron-hole pairs are generated in the depletion layer. The hole is then stored in the p-layer (photoreceptor) which is in negative potential. In FIG. 5(C), when the first gate electrode A is applied with for example −12V, then the holes developed and stored in the photoreceptor will be attracted by the negative potential of the gate electrode A, thus entrapped and stored in the potential well A formed therebeneath.

In FIG. 6(A), when the first gate electrode A goes back to 0V and the second gate electrode S is applied with −12V, then the holes stored in the first potential well A will be transferred to and stored in the second potential well S formed beneath the second gate electrode S. On the other hand, the photoreceptor continuously develops holes, however the first gate electrode A is now 0V, so that the holes will be stored in the P layer. In FIG. 6(B), when the gate electrode G of the read out circuit is applied with for example −5V, then the p-channel MOSFET becomes conductive, to read out the charge stored in the second potential well (source) S through the p-channel formed in the N layer to the drain circuit D. In FIG. 6(C), the photoreceptor is storing the photoelectric conversion charge for the next period of time T, and the transfer control for the next cycle will be conducted thereafter.

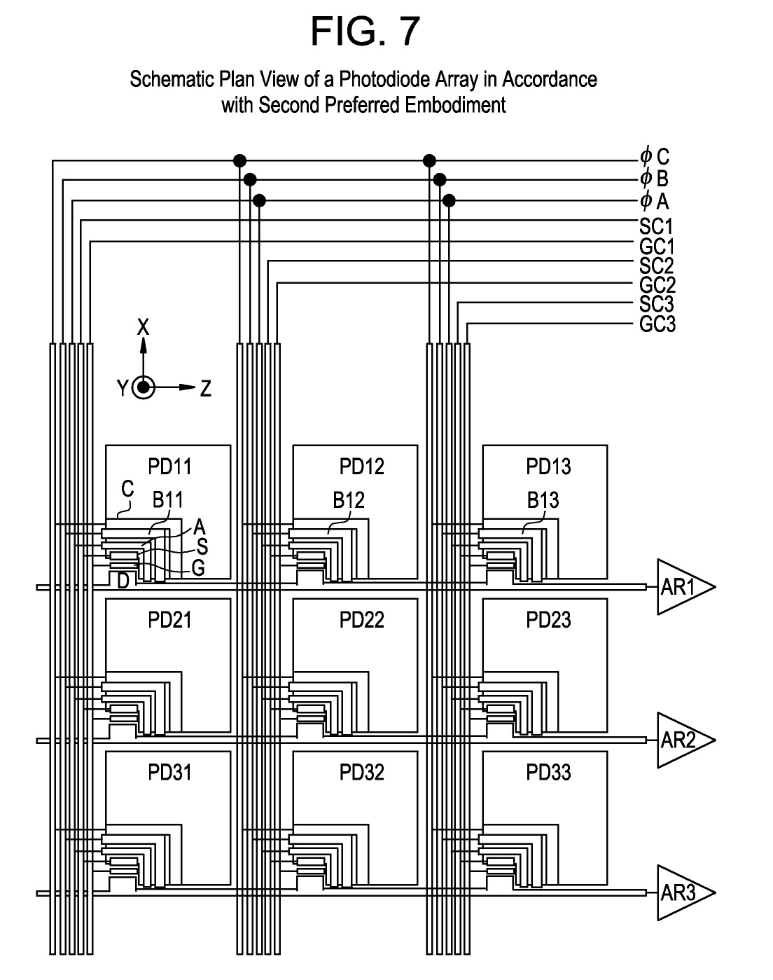

Now referring to FIG. 7, there is shown a schematic plan view of a photodiode array in accordance with the second preferred embodiment of the present invention, in which third and fourth gate electrodes C, B and an insulator layer therebetween are provided for forming third and fourth potential wells between the photoreceptor and the first potential well A, the photoelectric conversion charge to be stored in the photoreceptor for a predetermined period of time T is sequentially transferred to the third and fourth potential wells C, B at once for a plural of number of times, then the third potential well C is disappeared each time to form a potential barrier for blocking the transfer of charge between the photoreceptor and the fourth potential well B, then eventually total charge stored (integrated) in the fourth potential well B is transferred sequentially to the first and second potential wells at once.

In the second preferred embodiment, the third and fourth gate electrodes C, B are formed so as to surround the first gate electrode A to thereby form the third and fourth potential wells C, B, which enables insulating electrically the photoreceptor from the first potential well A. The third and fourth gate electrodes C, B are applied with third and fourth gate signals φ C, φ B, which signals are commonly applied to all PDs, PD11 to PD33. Other parts are just similar to the first preferred embodiment as have been described above (FIG. 3, etc.).

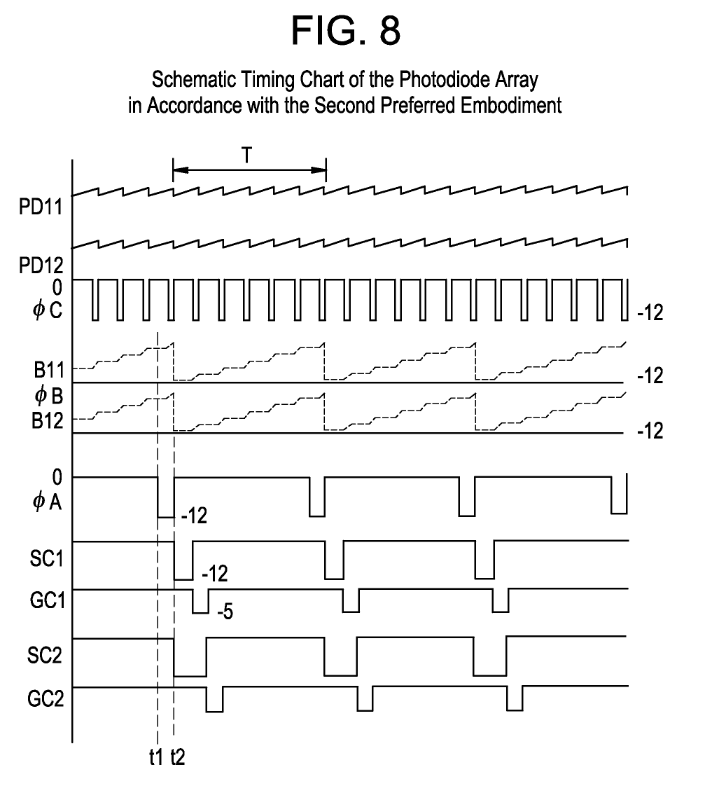

Now referring to FIG. 8, there is shown a timing chart of the photodiode array in accordance with the second preferred embodiment of the present invention. In the figure third gate signal φ C is applied for a plural number of times within the period of time T (for example, −12V), and the fourth gate signal φ B is biased for example to −12V. Total photoelectric conversion charge to be developed in the photoreceptor for the predetermined period of time T will thereby be sequentially transferred in a plural number of times to the fourth potential well and integrated (stored) therein. All the charge developed in the receptor is therefore stored in the fourth potential well with low less, allowing a high linearity in the photoelectric conversion characteristics.

Total charge integrated/stored in the fourth potential well B for the predetermined period of time T will be transferred to the corresponding first potential wells A at once, in a manner similar to the first preferred embodiment described above, triggered by the first gate signal φ A which is common to all PDs, then transferred at once to the corresponding second potential wells (source) S, triggered by the second gate signals SC1 to SC4, each of which are common to respective column. At this time, the first gate signal φ A is brought to high, so that the charge transferred to each second potential well S is held, and the charge stored in the second potential well S will be read out column by column in the time division basis.

In accordance with the second preferred embodiment of the present invention, All PDs are capable of detecting light in the same phase in a same cycle T, while the photoelectric conversion charge for the predetermined period of time T can be efficiently stored. The charge is read out from the second potential well (source) S of each column by the gate signals GC1 to GC4, which signals are shifted by the time Δt, on the time division basis, allowing a significant simplification of the read out circuitry (such as amplifiers).

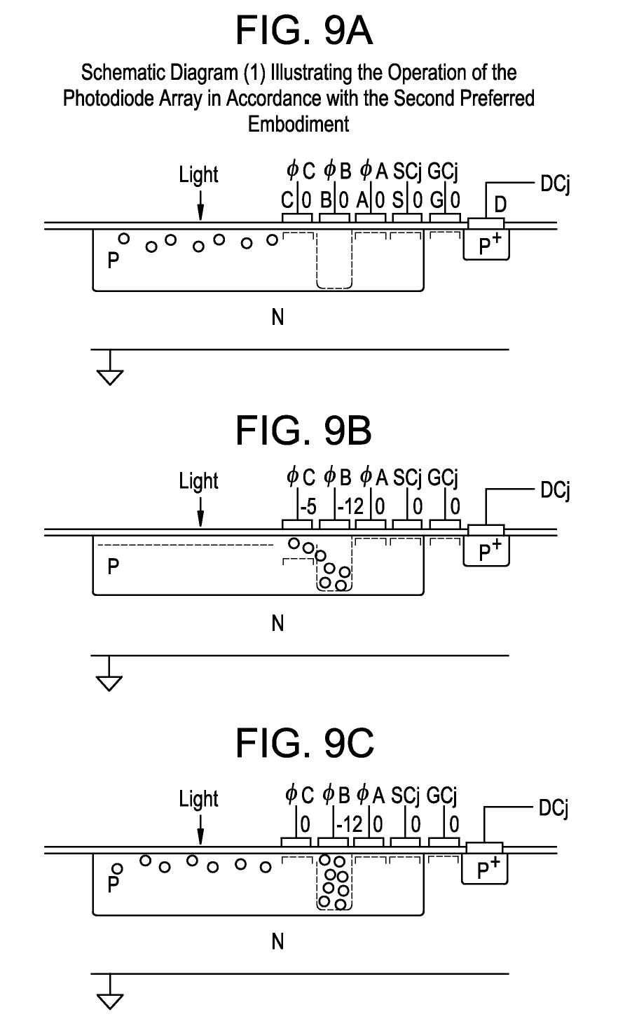

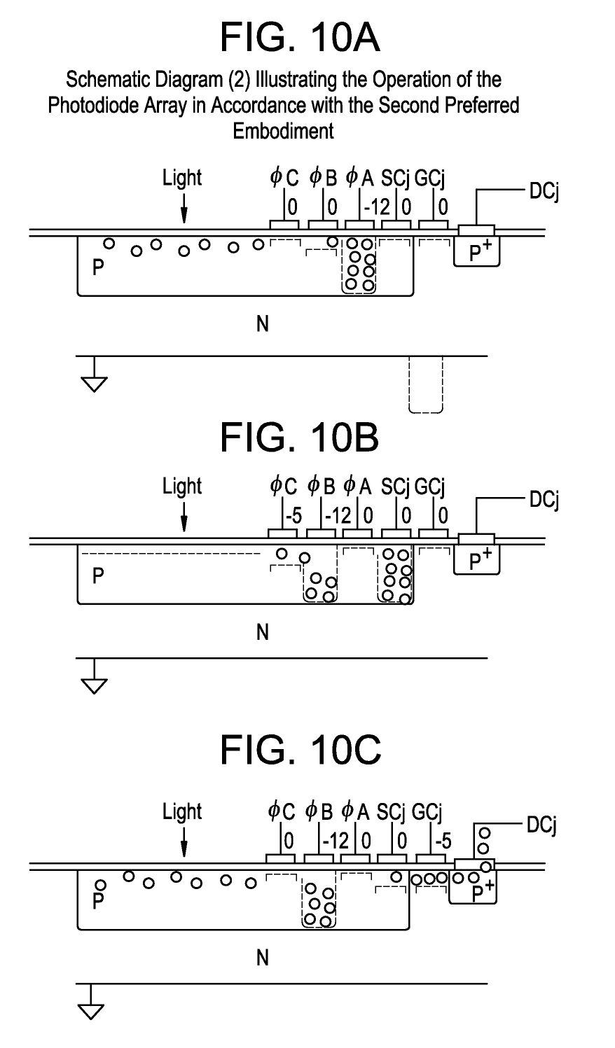

Now referring to FIG. 9 and FIG. 10, there is shown schematic diagrams (1), (2) illustrating the operation of photodiode array in accordance with the second preferred embodiment of the present invention. Referring to FIG. 9(A), in the second preferred embodiment, third and fourth gate electrodes C, B are further provided between the photoreceptor and the first gate electrode A, and third and fourth potential wells are forceable beneath these electrodes, respectively. When incident light comes into pn junction in such a configuration, electron-hole pairs are generated in the depletion zone, of which the holes will be accumulated in the p-layer (photoreceptor) which is in negative potential. In FIG. 9(B), the charge in the photoreceptor will be entrapped in the third potential well C each time a third gate signal φ C is pulsed, then is transferred and accumulated in the fourth potential well B biased by the gate signal φ B (−12V). In FIG. 9(C), the sequential transfer control is iteratively repeated for a while, and at the end of the period of time T, all charge generated in the photoreceptor for the period of time T is accumulated in the fourth potential well B. On the other hand, although holes are continuously generated in the photoreceptor, they are to be accumulated in the p-layer for a while because the third gate electrode C is brought back to 0V.

In FIG. 10(A), when the first gate electrode A is applied with −12V, all charge accumulated in the fourth potential well is transferred to the first potential well A. The fourth gate signal φ B is preferably momentarily biased to 0V so as to ensure the charge transfer. In FIG. 10(B), when the first gate signal φ A is brought to 0V and the second gate signals SC1-SC3 are applied, the charge transferred to the first potential well A is then transferred to the second potential well. In FIG. 10(B), when the gate electrode G of the read out circuit is applied with −5V, p-channel MOSFET becomes conductive to allow the charge accumulated in the second potential well S to be read out to the drain circuit D through the p-channel generated in the n-type layer.

In the above embodiment, charge is shifted by first and second gate signals φ A, SCj, and third and fourth gate signals φ C, φ B (two-phase clocked). The transfer direction of the charge in this case may be controlled by using the nature that the charge always moves in the oxide film from the thicker side (weaker electric field) to the thinner side (stronger electric field) if the thickness of the insulator layer (silicon oxide film SiO2) beneath each electrode to be asymmetric. As to the charge transfer, any other known types can be used.

Although in the above preferred embodiment there has been described a case in which holes developed in the p-type layer of a pn junction is used for the signal carrier, the present invention is not limited thereto. The electrons developed in the n-type layer are equally used for the signal carrier.

Although in the above preferred embodiment there has been described a case in which the image sensor in accordance with the present invention is used in an X-ray CT apparatus, the present invention is not limited thereto. The image sensor in accordance with the present invention can be applied to any other type of imaging devices (such as a camera).

Although there have been described a plurality of presently preferred embodiments of the present invention, various changes and modification may be made in the arrangement, control, process, and the combination thereof without departing from the spirit and scope of the invention.

1. An image sensor comprising: a plurality of two-dimensionally arrayed photodiodes; and a plurality of read out gate circuits for reading out the photoelectric conversion charge stored in the photoreceptor of each of the photodiodes, wherein:
first and second gate electrodes are provided via an insulator layer for forming a first and second potential well respectively in the vicinity of each of said photoreceptors;
charge stored in each photoreceptor for a predetermined period of time is sequentially transferred to the first and second potential wells each at once;
a potential barrier is formed for blocking the movement of charge between said photoreceptor and said second potential well by disappearing said first potential well; and
charge accumulated in said second potential well is read out to an outside in a time division basis.

2. An image sensor according to claim 1, wherein:
third and fourth gate electrodes are provided via an insulator layer for forming third and fourth potential wells between each of said photoreceptors and first potential well;
charge to be accumulated in each photoreceptor for said predetermined period of time is sequentially transferred to the third and fourth potential wells each at once for a plurality of times;
a potential barrier is formed each time for blocking the movement of charge between said photoreceptor and said fourth potential well by disappearing said third potential well; and
charge integrated in said fourth potential well is then sequentially transferred each at once to said first and second potential wells.

3. An image sensor according to claim 1, wherein:
an amplifier circuit common to either row or column of sensor elements arranged in a two-dimensional array; and
charge accumulated in the second potential well of each sensor element is read out to an outside in a time division basis in the row or column direction.

4. An image sensor controlling method for an image sensor comprising: a plurality of two-dimensionally arrayed photodiodes; first and second gate electrodes provided to form respectively first and second potential wells in the vicinity of the photoreceptor of each of said photodiodes; and a plurality of read out gate circuits for reading out charge stored in said second potential well, the method comprising the steps of:
accumulating into said photoreceptor the charge generated in the photoreceptor for a predetermined period of time;
sequentially transferring the charge accumulated in said photoreceptor each at once to first and second potential wells, then forming a potential barrier for blocking the movement of charge between said photoreceptor and second potential well by disappearing said first potential well; and
reading out the charge stored in said second potential well in a time division basis.

5. An image sensor controlling method of an image sensor comprising: a plurality of photodiodes arranged in a two-dimensional array; third and fourth and first and second gate electrodes provided to form respectively third and fourth and first and second potential wells in the vicinity of the photoreceptor of each of said photodiodes; and a read out gate circuit for reading out the charge accumulated ultimately in said second potential well, the method comprising the steps of:
sequentially transferring the charge to be stored in each of the photoreceptors for a predetermined period of time each at once to the third and fourth potential wells for a plurality of times, then forming a potential barrier for blocking the movement of charge between said photoreceptor and the fourth potential well by disappearing said third potential well;
sequentially transferring charge integrated in said fourth potential well each at once to said first and second potential wells and then forming a potential barrier for blocking the movement of charge between said fourth potential well and second potential well by disappearing said first potential well; and
reading out the charge accumulated in said second potential well in a time division basis.

6. An X-ray detector, comprising:
a scintillator layer for converting X-ray into light, said scintillator being fixedly laminated on the light receiving plane of the image sensor according to claim 1.

7. An X-ray detector of an X-ray CT apparatus including an X-ray tube and the X-ray detector according to claim 6, placed in the opposing sides of a subject, for reconstructing a CT tomographic image of the subject based on the projection data obtained by scanning the subject, wherein:
the detector comprises a common amplifier circuit in the slice direction of each channel of the sensor elements arranged in a two-dimensional array extending in the slice direction which is in parallel to the body axis of the subject, and in the channel direction which is perpendicular thereto, and reads out the charge stored in the second potential well of each sensor element arranged in the channel direction at once, and the charge stored in the second potential well of each sensor element arranged in the slice direction in a time division basis.

8. An X-ray CT apparatus comprising the X-ray CT detector according to claim 7.
